(19) United States
(12) Patent Application Publication
(10) Pub. No.: US 2025/0183116 A1
(43) Pub. Date: Jun. 5, 2025

(54) METAL-CERAMIC COMPOSITE

(71) Applicant: Heraeus Electronics GmbH & Co. KG, Hanau (DE)

(72) Inventors: Richard WACKER, Hanau (DE); Leszek NIEWOLAK, Hanau (DE); Stefanie STOICA, Hanau (DE); Bastian SCHLÜTER, Hanau (DE); Daniel SCHNEE, Hanau (DE)

(21) Appl. No.: 18/962,570

(22) Filed: Nov. 27, 2024

(30) Foreign Application Priority Data
Nov. 30, 2023 (EP) 23213371.0

(51) Int. Cl. H01L 23/373; C04B 35/584; C04B 41/45; C04B 41/51; C04B 41/88

(52) U.S. Cl. CPC H01L 23/3731; C04B 35/584; C04B 41/4556; C04B 41/4572; C04B 41/5127; C04B 41/5155; C04B 41/88

(57) ABSTRACT

A metal-ceramic composite containing a ceramic substrate comprising a front side and a rear side and containing a silicon nitride, a metal coating present on the front side of the ceramic substrate, wherein the metal coating comprises at least one recess, and a surface of the ceramic substrate is exposed by the recess, wherein the surface of the ceramic substrate exposed by the recess has a stretched surface area ratio S_{dr} in accordance with the standard ILNAS-EN ISO 25178-2:2022 of at least 7.0%, wherein S_{dr} is determined by confocal microscopy.

### CROSS-REFERENCE TO RELATED APPLICATIONS

This application claims priority pursuant to 35 U.S.C. 119(a) to European Patent Application No. 23213371.0, filed Nov. 30, 2023, which application is incorporated herein by reference in its entirety.

### FIELD OF THE INVENTION

The present invention relates to a metal-ceramic composite which can be used as a ceramic circuit carrier in power electronics.

### BACKGROUND OF THE INVENTION

In power electronics, printed circuit boards must be designed for high currents as carriers for power components such as MOSFETs and be able to quickly dissipate waste heat.

Since ceramic materials such as aluminum oxide, aluminum nitride, and silicon nitride have a much higher thermal conductivity than polymers used to produce conventional printed circuit boards, ceramic circuit carriers are often used in power modules.

Ceramic substrates based upon silicon nitride have very high mechanical strength and at the same time high thermal conductivity and are therefore very suitable for applications in power electronics.

Ceramic substrates based upon silicon nitride are described, for example, in the following publications:
N. Chasserio et al., “Ceramic Substrates for High-Temperature Electronic Integration,” Journal of Electronic Materials, Volume 38 (2009), pp. 164-174;
K. Hirao et al., “High Thermal Conductivity Silicon Nitride Ceramics,” Journal of the Korean Ceramic Society, Volume 49 (2012), pp. 380-384;
Y. Zhou et al., “Development of high-thermal-conductivity silicon nitride ceramics,” Journal of Asian Ceramic Societies, 3 (2015), pp. 221-229.

Silicon nitride-based ceramic substrates, which show a good compromise between high mechanical strength and high thermal conductivity and can be used in electronic components, are commercially available.

A ceramic circuit carrier contains a ceramic substrate which is provided with a metal layer on at least one of its sides, usually on both sides. In the final module, the semiconductor components are applied to one of these metal layers, while the metal layer on the opposite side of the ceramic substrate is thermally connected to a heat sink. The ceramic substrate electrically insulates the metal layers from each other.

The production, known to a person skilled in the art, of a metallized ceramic substrate functioning as a ceramic circuit board is carried out, for example, by bringing the front and rear sides of the ceramic substrate into contact with a metal foil (e.g., a copper or aluminum foil) and bonding them together. The material bonding of the metal foils is achieved, for example, by eutectic bonding or active metal brazing (AMB). If the metal foil is a copper foil, eutectic bonding is also known as the DCB or DBC process (DCB: “direct copper bonding”; DBC: “direct bonded copper”). In the case of aluminum foil, the term “DAB” (“direct aluminum bonding”) is also used for eutectic bonding. A metallized ceramic substrate produced using a DCB or AMB process is sometimes also referred to as a DCB substrate (alternatively: DBC substrate) or AMB substrate.

The metallization of silicon nitride substrates is usually carried out by active metal brazing.

Active metal brazes contain, in addition to a main component such as Cu, Ag, or Au, one or more elements that can react with the ceramic to form an adhesion-promoting reaction layer (see, for example, Chapter 8.2.4.3 (“Active metal brazing”), pages 203-204, in Brevier Technische Keramik, Verband der Keramischen Industrie eV, 2003, Fahner Verlag). Reactive elements such as hafnium (Hf), titanium (Ti), zirconium (Zr), niobium (Nb), cerium (Ce), tantalum (Ta), and vanadium (V) are used. In the metallization of silicon nitride substrates by active metal brazing, the reaction layer contains, for example, a nitride, oxynitride, and/or silicide of the reactive element (A. Ponicke et al., “Active metal brazing of copper with aluminum nitride and silicon nitride ceramics”, Keramische Zeitschrift, 63(5), 2011, 334-342).

The metal layer carrying the semiconductor components comprises one or more recesses and is therefore also referred to as a structured metal coating. By structuring, for example, metallic conductor tracks are formed on the ceramic substrate. Adjacent conductor tracks are spatially separated by the recesses and are therefore electrically insulated from each other. The structuring of AMB substrates can, for example, be carried out in a two-stage process, wherein, in a first step, the metal layer is first removed in defined regions (e.g., using a first etching solution), and then, in a second step, the adhesion-promoting layer resulting from the active metal brazing process is removed (e.g., using a second etching solution). By removing the metal layer and, if applicable, the adhesion-promoting layer, the ceramic substrate is exposed again in defined regions.

Modules based upon ceramic circuit carriers used in power electronics can be encapsulated as part of the packaging process, for example, by embedding the power module in a casting compound.

For example, embedding in a casting compound increases the electrical breakdown strength. In addition, the semiconductor components and metal conductor tracks are protected from humidity and mechanically stabilized.

In the regions exposed by the structuring, the ceramic substrate comes into direct contact with the casting compound. When operating a power module, significant temperature fluctuations can occur. Since ceramic materials and the casting compound usually have significantly different thermal expansion coefficients, these temperature fluctuations result in mechanical stresses at the interface between the ceramics and the casting compound. This in turn can result in the casting compound becoming at least partially detached from the ceramic substrate and in cavities forming. Humidity that penetrates these cavities can damage the power module. In addition, there may be a significant reduction in the electrical breakdown strength, at least locally.

As already mentioned above, ceramic substrates based upon silicon nitride are used as circuit carriers in power electronics due to their very high mechanical strength and high thermal conductivity. In order to make the most of their potential as circuit carriers, it would be desirable for there to be a high adhesion strength between the casting compound and the silicon nitride surface after embedding in a casting compound.

JP 2018-046192 A describes a ceramic-metal composite that is embedded in a polymeric casting compound. Silicon nitride ceramic is used as the ceramic substrate. Exposed regions of the ceramic surface of the ceramic-metal composite are treated with a particulate blasting media so that, in these treated regions, the ceramic surface has a maximum profile height Ry of 1.7 μm to 2.7 μm. According to JP 2018-046192 A, this should ensure good adhesion of the casting compound to the ceramic substrate.

### SUMMARY OF THE INVENTION

An object of the present invention is to provide a metallized silicon nitride-containing ceramic substrate whose exposed ceramic surface allows for the formation of a bond of high adhesion strength with a polymeric casting compound.

This object is achieved by a metal-ceramic composite containing
a ceramic substrate comprising a front side and a rear side and containing a silicon nitride,
a metal coating present on the front side of the ceramic substrate, wherein the metal coating comprises at least one recess, and a surface of the ceramic substrate is exposed by the recess, wherein the surface of the ceramic substrate exposed by the recess has a stretched surface area ratio S_{dr} in accordance with the standard ILNAS-EN ISO 25178-2:2022 of at least 7.0%.

### DETAILED DESCRIPTION OF THE INVENTION

As is well known, the roughness of a surface can be determined from the profile (i.e., along a line) or on the surface. Various roughness parameters are available for both profile and area measurements. In the ISO 4287 standard, certain roughness parameters are defined for the profile, such as the arithmetic mean deviation Rₐ (also called arithmetic mean roughness value) or the maximum height R_{z} of the profile. Roughness parameters determined on the surface are defined in the EN ISO 25178 series of standards and include, for example, the arithmetic mean height Sₐ, the maximum height S_{z}, and the stretched surface area ratio S_{dr}. Compared to profile parameters, the roughness of a surface can be determined much more reliably using surface parameters. Optical measuring methods such as confocal microscopy are used to determine the surface parameters.

The stretched (or “developed”) surface area ratio S_{dr} according to ILNAS-EN ISO 25178-2:2022 describes the relationship between an ideally flat surface and a real measuring surface, and is therefore a measure of the roughness of the surface. The stretched surface area ratio S_{dr} is also known as the “developed interfacial area ratio” and indicates the percentage increase in the actual surface area compared to the projected (and thus perfectly planar) surface area. Thus, if the actual surface were perfectly planar, S_{dr} would be 0%. For example, if the actual surface is 2 times larger than the projected surface, S_{dr} is 100%. If the area increases by a factor of 2.5, S_{dr} is 150%.

While the parameters Sₐ and S_{z} are pure height parameters, i.e., they provide only information in the z-direction of the surface being tested, S_{dr} is a so-called hybrid parameter, the value of which depends not only upon the height of the surface elevations, but also upon the distance between adjacent elevations.

Within the scope of the present invention, it was recognized that the adhesion strength of a casting compound on the ceramic substrate can be improved if the exposed surface of the ceramic substrate has a stretched surface area ratio S_{dr} of at least 7.0%. The determination of the stretched surface area ratio S_{dr} is carried out by confocal microscopy.

Preferably, the stretched surface area ratio S_{d}r of the surface of the ceramic substrate exposed by the recess is at least 9.2%.

In an exemplary embodiment, the stretched surface area ratio S_{dr} of the surface of the ceramic substrate exposed by the recess is 7.0% to 20.0%, more preferably 9.2% to 15.0%.

If the stretched surface area ratio S_{d}r exceeds 20%, the risk of damage to the ceramic substrate increases, which in turn adversely affects the mechanical properties such as the bending strength of the ceramic substrate.

For example, the surface of the ceramic substrate exposed by the recess has a maximum height S_{z} in accordance with the standard ILNAS-EN ISO 25178-2:2022 of 8 μm to 20 μm, more preferably 10 μm to 15 μm. The maximum height S_{z} is determined by confocal microscopy.

In an exemplary embodiment, the surface of the ceramic substrate exposed by the recess has a stretched surface area ratio S_{dr} of 7.0% to 20.0% and a maximum height S_{z} of 8 μm to 20 μm, more preferably a stretched surface area ratio S_{dr} of 9.2% to 15.0% and a maximum height S_{z} of 10 μm to 15 μm.

The ceramic substrate contains silicon nitride. Ceramic substrates based upon silicon nitride, which are suitable for the production of power modules, are known to a person skilled in the art and are commercially available.

For example, the ceramic substrate contains silicon nitride in a proportion of at least 70 wt. %, more preferably at least 80 wt. %.

Optionally, the ceramic substrate may contain one or more metal oxides. These were added, for example, as sintering aids during the production of the ceramic substrate. Suitable oxide components for silicon nitride ceramics are known to a person skilled in the art. For example, the ceramic substrate contains one or more of the following oxides: one or more alkaline earth metal oxides such as magnesium oxide, one or more transition metal oxides (e.g., one or more rare earth oxides such as yttrium oxide or erbium oxide), a silicon oxide (e.g., SiO₂), or a silicate. Silicon nitride, for example, is present as β-silicon nitride.

The ceramic substrate, for example, has a thickness in the range of 0.1 mm to 1.0 mm.

On the front side of the ceramic substrate, there is a metal coating which comprises at least one recess, so that a surface of the ceramic substrate is exposed by the recess. This metal coating is also referred to as structured metal coating. The semiconductor components can be attached to the structured metal coating.

Optionally, a metal coating is also available on the rear side of the ceramic substrate. This rear side metal coating can optionally also comprise at least one recess, through which a surface of the ceramic substrate is exposed. In order to achieve the most efficient heat dissipation possible, it may be preferable for the rear side metal coating not to comprise such a recess.

The metal coating present on the front side and optionally the rear side of the ceramic substrate is, for example, a copper coating or an aluminum coating. The metal coating has, for example, a thickness in the range of 0.05 mm to 1.5 mm, more preferably 0.2 mm to 0.8 mm.

If the metal coating is a copper coating, it comprises, for example, a copper content of at least 97 wt. %, more preferably at least 99 wt. %.

If the metal coating is an aluminum coating, it comprises, for example, an aluminum content of at least 97 wt. %, more preferably at least 99 wt. %.

The metal coating can be applied to the front side and optionally the rear side of the ceramic substrate using methods known to a person skilled in the art.

For example, a metal foil (e.g., a copper or aluminum foil) is bonded to the front side of the ceramic substrate by active metal brazing.

In active metal brazing, for example, a connection is made between the metal foil and the ceramic substrate using an active metal braze at a temperature of approximately 600-1,000° C. Due to their alloy composition, active metal brazes are able to wet non-metallic, inorganic materials such as ceramic substrates. In addition to a main component such as copper, silver, and/or gold, active metal brazes also contain one or more active metals such as Hf, Ti, Zr, Nb, V, Ta, or Ce, which can react with the ceramic substrate to form a reaction layer.

Preferably, a reaction layer resulting from the active metal brazing is present between the metal coating and the front side of the ceramic substrate. The reaction layer contains, for example, one or more elements E_{RS}, selected from Hf, Ti, Zr, Nb, V, Ta, and Ce, preferably selected from Hf, Ti, Zr, Nb, and Ce, more preferably selected from Hf, Ti, and Zr. The element E_{RS} in the reaction layer is particularly preferably titanium. For example, the elements E_{RS} are present in the reaction layer in the form of a nitride, oxynitride, and/or silicide. For example, the reaction layer contains the elements E_{RS} in a total amount of at least 50 wt. %. For example, the reaction layer contains the nitrides, oxynitrides, and silicides of the elements ESR in a total amount of at least 70 wt. %, more preferably at least 85 wt. %. In a power electronics semiconductor module, the migration of silver can cause problems. It may therefore be preferred that the reaction layer contain silver in a proportion of not more than 5 wt. %, more preferably not more than 1 wt. %, or even be silver-free.

Exposing a surface of the ceramic substrate takes place, for example, in several steps. First, the metal coating is removed, e.g., by etching, and the reaction layer formed during active metal brazing is exposed. The exposed reaction layer is then removed, e.g., by etching or laser ablation. Preferably, the exposed reaction layer is removed using an ultrashort pulse laser (e.g., an IR picosecond or femtosecond laser).

In order to electrically insulate the regions of the metal coating separated from each other by the recess, it would be sufficient to carry out the single- or multi-stage removal only for as long as or under such conditions until the exposed reaction layer has been completely removed in the treated regions, but the ceramic substrate has not yet been removed by the removal medium (e.g., the etching medium or the pulsed laser).

Within the scope of the present invention, however, the exposure of the ceramic substrate surface is preferably carried out such that the removal medium (preferably an ultrashort pulse laser, e.g., a picosecond or femtosecond laser) not only completely removes the exposed reaction layer, but also ablates ceramic material until the exposed surface of the ceramic substrate has a stretched surface area ratio S_{dr} of at least 7.0%.

A suitable treatment duration and suitable parameters of the removal medium can easily be determined by a person skilled in the art through a series of tests.

For setting a stretched surface area ratio S_{dr} in the range according to the invention, it has proven advantageous if the laser beam is moved over the surface in parallel scan lines during the removal of the reaction layer and the subsequent roughening of the exposed surface of the ceramic substrate, and if intersecting scan lines are avoided as far as possible. The pulse energy of the laser pulses is selected to be sufficiently high to cause material removal along the scan lines.

For example, at least 50%, preferably at least 70%, of the surface of the ceramic substrate exposed by the recess or even substantially the entire surface of the ceramic substrate exposed by the recess can have the stretched surface area ratio S_{dr} according to the invention and optionally the maximum height S_{z} stated above.

An exposed surface of the ceramic substrate having a stretched surface area ratio S_{dr} of at least 7.0% results in improved adhesion strength of a casting compound to the ceramic substrate.

The present invention also relates to a semiconductor module, containing the metal-ceramic composite described above and one or more semiconductor components.

Preferably, the semiconductor module also contains a casting compound, wherein the casting compound contacts the surface of the ceramic substrate of the metal-ceramic composite exposed by the recess.

Casting compounds for electronic components are known to a person skilled in the art. The casting compound contains, for example, a polymer (e.g., a thermoplastic or thermo setting polymer). For example, the casting compound contains an optionally cured epoxy resin or silicone resin, a polyurethane, or an inorganic cement (e.g., a phosphate cement).

### Measurement Methods

Determination of the Stretched Surface Area Ratio S_{dr} and the Maximum Height S_{z}

To determine the stretched surface area ratio S_{dr} and the maximum height S_{z}, 3-D images of the ceramic substrate surface were taken using the confocal microscope μsurf custom (NanoFocus AG, Germany), which imaged at least 800 μm×800 μm of the exposed surface of the ceramic substrate. By means of the software Soft Analysis Premium (7.4.8872; NanoFocus AG, Germany), the microscopic 3-D images were analyzed. For this purpose, any deflection of the bonding substrate in the 3-D images was initially corrected (use of a polynomial of degree 2). The stretched surface area ratio S_{dr} and the maximum height S_{z} were then determined according to the standard ILNAS-EN ISO 25178-2:2022.

### Composition of the Adhesion-Promoting Layer

The composition of the adhesion-promoting layer is determined by energy-dispersive X-ray spectroscopy (EDX) coupled with scanning electron microscopy (SEM-EDX).

In REM-EDX, a focused primary electron beam is guided (screened) over the sample surface point by point. The scattered electrons are detected using a detector, wherein the number of electrons per pixel results in a microscopic image of the sample surface in grayscale. In addition, the primary electron beam excites the sample to emit characteristic X-ray radiation, wherein the elements in the sample and their weight proportion can be determined by analyzing the energy spectrum using an EDX detector. For the examination, a scanning electron microscope (JSM-6060 SEM, JEOL, Ltd.) with a silicon drift EDX detector (NORAN, Thermo Scientific, Inc.) and analytical software (Pathfinder Mountaineer EDS System, e.g., Version 2.8, Thermo Scientific, Inc.) is used, for example. For scanning electron microscopy, the following settings are used: magnification: 1,000-fold, acceleration voltage=15 kV, working distance=10 mm, spot size (50-60) (adjusted to reach 25%+/−5% of the dead time of the EDX detector). The EDX spectrum was detected using the following settings of the EDX detector: live time=30 s, rate=auto, low energy cutoff=100 keV, high energy cutoff=auto (per SEM acceleration voltage).

By means of SEM-EDX, the composition of the adhesion-promoting layer can be determined both qualitatively (detection of certain elements and phases, e.g., a metal nitride phase present in the adhesion-promoting layer) and quantitatively. For example, the measurement is carried out at at least 10 points on the adhesion-promoting layer.

### Examples

Four individual silicon nitride substrates were separated from a silicon nitride starting substrate that had predetermined breaking points for separation. The ceramic substrates S1-S4 had matching dimensions (174 mm×139 mm×0.32 mm).

For each of the individual silicon nitride substrates, S_{z} and S_{dr} were determined in the region of the front side that will later be exposed again after metallization. The substrates showed substantially matching S_{dr} values. The ceramic substrates also substantially matched in their S_{z} values. S_{dr} of the starting substrates: 5.0%+/−0.5%

$${S}_{z} : 5.9 \text{+/-} 0.9 μm$$

The silicon nitride substrates were metallized by identical active metal brazing processes under the conditions described below.

On one of the sides of the ceramic substrate, an active metal brazing paste was applied by screen printing on an area measuring 168 mm×130 mm and pre-dried for 15 minutes at 125° C. The active metal brazing paste consisted of 67 wt. % copper powder, 19.8 wt. % tin powder, 3.7 wt. % titanium hydride, and 9.5 wt. % of an organic vehicle. The paste thickness after pre-drying was 25+/−5 μm. Subsequently, a copper foil made of oxygen-free, highly conductive copper with a purity of 99.99% and dimensions of 170 mm×132 mm×0.3 mm was placed on the pre-dried paste. The resulting arrangement was then turned over, the paste was similarly applied to the opposite side of the ceramic substrate by screen printing, pre-dried, and fitted with a copper foil, to obtain a sandwich arrangement. The sandwich arrangement was weighted with a weight of 1 kg, fired at a maximum temperature of 910° C. for 20 minutes, and then cooled to room temperature to obtain an unstructured metal-ceramic composite. Due to the production by active metal brazing, an adhesion-promoting reaction layer is present between the metal coating and the ceramic substrate. Said reaction layer contains titanium (e.g., in the form of a nitride).

Each of the three metal-ceramic composites was subjected to a first structuring process using an etching solution containing CuCl₂. The metal coating in the etched regions on the front side of the ceramic substrate was substantially completely removed. However, the reaction layer resulting from the active metal brazing process was not removed by the CuCl₂-containing etching solution.

In comparative example VB1, the exposed reaction layer was removed with an etching solution containing ammonium fluoride, fluoroboric acid, and hydrogen peroxide.

In the examples EB1 and EB2 according to the invention, as well as the comparative example VB2, the exposed adhesion-promoting layer was removed by laser treatment with a pulsed laser beam. In comparative example VB2, a laser beam with a relatively low pulse energy was used, so that only a small amount of material was removed. In the examples EB1 and EB2 according to the invention, the same pulse energy was used, which was increased compared to the pulse energy used in the comparative example VB1, and therefore resulted in a higher material removal. In EB1, the laser beam was guided on intersecting scan lines, while in EB2 the laser was guided on parallel scan lines.

For the exposed ceramic surfaces of the examples EB1 and EB2 according to the invention, as well as the comparative examples VB1 and VB2, the stretched surface area ratio S_{dr} and the maximum height S_{z} were measured. Subsequently, a casting compound was applied to each of the exposed ceramic surfaces, and the adhesion strength was determined.

The adhesion strength was determined as follows:

To determine the adhesion of a casting compound (silicone), two plates (size of the plates: 20×20×0.32 mm) were cut out of each of the exposed regions of the respective ceramic substrate. The two plates, which were taken from the same ceramic substrate, were then bonded to form a test specimen by means of Sylgard 527 silicone. The overlap of both plates was 1 cm, so that the adhesive surface was always 2 cm². The silicone was cured in air for 2 hours at 125° C. Each test specimen was compressed with a weight of 50 g to produce a uniformly thin silicone layer.

The test specimens thus produced were tested for shear strength (testing machine: model zwicki500, ZwickRoell GmbH & Co. KG). The maximum shear force was determined in each case.

The results are summarized in Table 1 below.

TABLE 1
S_{dr} and S_{z} values of the exposed ceramic surfaces and adhesion strengths
between the exposed ceramic surfaces and a casting compound

| Example | S_{dr} (%) | S_{z} (μm) | Adhesion strength (N) |
|---|---|---|---|
| VB1 | 5.2 | 6.1 | 3.4 |
| VB2 | 6.05 | 7.35 | 5.2 |
| EB1 | 8.25 | 14.1 | 15.5 |
| EB2 | 9.71 | 13.7 | 25.1 |

The examples demonstrate that a significant improvement in the adhesion strength of the casting compound to the exposed ceramic surface is achieved when the stretched surface area ratio S_{dr} is within the range according to the invention.

1. A metal-ceramic composite, containing
a ceramic substrate comprising a front side and a rear side and containing a silicon nitride,
a metal coating present on the front side of the ceramic substrate, wherein the metal coating comprises at least one recess, and a surface of the ceramic substrate is exposed by the recess, wherein the surface of the ceramic substrate exposed by the recess has a stretched surface area ratio S_{dr} in accordance with the standard ILNAS-EN ISO 25178-2:2022 of at least 7.0%, wherein S_{dr} is determined by confocal microscopy.

2. The metal-ceramic composite according to claim 1, wherein the stretched surface area ratio S_{dr} of the surface of the ceramic substrate exposed by the recess is 7.0% to 20.0%, more preferably 9.2% to 15.0%.

3. The metal-ceramic composite according to claim 1, wherein the surface of the ceramic substrate exposed by the recess has a maximum height S_{z} in accordance with the standard ILNAS-EN ISO 25178-2:2022 of 8 μm to 20 μm, wherein S_{z} is determined by confocal microscopy.

4. The metal-ceramic composite according to claim 1, wherein the metal coating is a copper or aluminum coating.

5. The metal-ceramic composite according to claim 1, wherein a reaction layer is present between the ceramic substrate and the metal coating, wherein the reaction layer contains one or more elements E_{RS} selected from Ti, Hf, Zr, Nb, V, Ta, and Ce.

6. A semiconductor module, containing the metal-ceramic composite according to claim 1, one or more semiconductor components.

7. The semiconductor module according to claim 6, further containing a casting compound, wherein the casting compound contacts the surface of the ceramic substrate of the metal-ceramic composite exposed by the recess.
